(19) United States
(12) Patent Application Publication
(10) Pub. No.: US 2005/0012224 A1
(43) Pub. Date: Jan. 20, 2005

(54) Semiconductor device, semiconductor module, electronic device and electronic equipment, and method for manufacturing semiconductor module

(76) Inventor: Hideki Yuzawa, Iida-shi (JP)

Correspondence Address: HARNESS, DICKEY & PIERCE, P.L.C., P.O. BOX 828, BLOOMFIELD HILLS, MI, 48303, US

(21) Appl. No.: 10/863,821

(22) Filed: Jun. 8, 2004

(30) Foreign Application Priority Data
Jun. 9, 2003 (JP) 2003-163830

(51) Int. Cl. H01L 21/48; H01L 21/44

(52) U.S. Cl. 257/778; 438/106

(57) ABSTRACT

A semiconductor device is provided. The device comprises a semiconductor chip and protruded electrodes arranged on the semiconductor chip in a staggered configuration. One row of the protruded electrodes in the staggered arrangement is offset with respect to another row of the protruded electrodes in the staggered arrangement.

### RELATED APPLICATIONS

This application claims priority to Japanese Patent Application No. 2003-163830 filed Jun. 9, 2003 which is hereby expressly incorporated by reference herein in its entirety.

### BACKGROUND

Technical Field of the Invention

The present invention relates to semiconductor devices, semiconductor modules, electronic devices and electronic equipment, and methods for manufacturing semiconductor modules, and in particular, is preferably applied when radially extending lead electrodes are used.

Conventional Technology

Concerning conventional semiconductor devices, for example, Japanese Laid-open Patent Application HEI 7-335692 describes a method for mounting a semiconductor chip on a film substrate by bonding protruded electrodes onto lead electrodes formed on the film substrate.

However, in the conventional semiconductor device, the protruded electrodes are disposed on the semiconductor chip at equal intervals. For this reason, if the lead electrodes are radially extended, the protruded electrodes are close to the lead electrodes adjacent thereto, which causes a problem in that it becomes difficult to secure clearances between the protruded electrodes and the lead electrodes adjacent thereto.

Accordingly, it is an object of the present invention to provide semiconductor devices, semiconductor modules, electronic devices and electronic equipment, and methods for manufacturing semiconductor modules, which are capable of increasing clearances between radially extending lead electrodes and protruded electrodes.

### SUMMARY

To solve the aforementioned problems, a semiconductor device in accordance with an embodiment of the present invention is characterized in comprising: a semiconductor chip; and protruded electrodes arranged on the semiconductor chip in a straight line configuration and having bonding surfaces that are each in a square shape or in a circular shape.

Accordingly, compared to the case where protruded electrodes are each in a rectangular shape, the protruded electrodes can be removed away from adjacent ones of the lead electrodes that extend diagonally. For this reason, even in the case where lead electrodes are radially extended, clearances between the protruded electrodes and adjacent ones of the lead electrodes can be increased, and positioning of the lead electrodes with respect to the protruded electrodes can be readily performed.

Also, a semiconductor device in accordance with an embodiment of the present invention is characterized in comprising: a semiconductor chip; and protruded electrodes arranged on the semiconductor chip in a staggered configuration, wherein one row of the arrangement is disposed offset with respect to another row of the arrangement.

Accordingly, even when lead electrodes are extended in a diagonal direction, the position of the protruded electrodes can be adjusted such that the protruded electrodes do not contact adjacent ones of the lead electrodes. For this reason, even in the case where lead electrodes are radially extended, clearances between the protruded electrodes and adjacent ones of the lead electrodes can be increased, and positioning of the lead electrodes with respect to the protruded electrodes can be readily performed, while accommodating lead electrodes arranged at a narrower pitch.

Also, a semiconductor device in accordance with an embodiment of the present invention is characterized in that bonding surfaces of the protruded electrodes are each in a square shape or in a circular shape.

Accordingly, compared to the case where protruded electrodes are each in a rectangular shape, the protruded electrodes can be removed away from adjacent ones of the lead electrodes that are diagonally extended. For this reason, even in the case where lead electrodes are radially extended, clearances between the protruded electrodes and adjacent ones of the lead electrodes can be increased, and positioning of the lead electrodes with respect to the protruded electrodes can be readily performed, while accommodating lead electrodes arranged at a narrower pitch.

Also, a semiconductor module in accordance with an embodiment of the present invention is characterized in comprising: a circuit substrate having radially extending lead electrodes formed thereon; a semiconductor chip mounted on the circuit substrate; and protruded electrodes disposed on the semiconductor chip and shifted in a direction away from adjacent ones of the lead electrodes. Accordingly, even when lead electrodes are extended in a diagonal direction, the position of the protruded electrodes can be adjusted such that the protruded electrodes do not contact adjacent ones of the lead electrodes. For this reason, even in the case where lead electrodes are radially extended, clearances between the protruded electrodes and adjacent ones of the lead electrodes can be increased, and positioning of the lead electrodes with respect to the protruded electrodes can be readily performed. As a result, even when the arrangement pitch of the lead electrodes changes when the circuit substrate expands or contracts due to heat and/or humidity, the narrow pitch of the lead electrodes can be accommodated and the lead electrodes and the protruded electrodes can be connected with good precision, and the reliability of the semiconductor module can be improved while the semiconductor module can be made smaller and lighter.

Also, a semiconductor module in accordance with an embodiment of the present invention is characterized in that the amounts of deviation of the protruded electrodes are adjusted based on inclinations of the lead electrodes.

Accordingly, even in the case where extending directions of the lead electrodes are different from one another, the position of the protruded electrodes can be adjusted such that the protruded electrodes do not come too close to the lead electrodes. For this reason, even in the case where lead electrodes are radially extended, clearances between the protruded electrodes and adjacent ones of the lead electrodes can be increased, and positioning of the lead electrodes with respect to the protruded electrodes can be readily performed, while accommodating changes in the arrangement pitch of the lead electrodes.

Also, a semiconductor device in accordance with an embodiment of the present invention is characterized in comprising: a circuit substrate having radially extending lead electrodes formed thereon; an electronic device mounted on the circuit substrate; and connection terminals disposed on the electronic device and shifted in a direction away from adjacent ones of the lead electrodes.

Accordingly, even in the case where lead electrodes are extended in a diagonal direction, the position of the connection terminals can be adjusted such that the connection terminals do not contact adjacent ones of the lead electrodes. For this reason, even in the case where lead electrodes are radially extended, clearances between the connection terminals and adjacent ones of the lead electrodes can be increased, and positioning of the lead electrodes with respect to the connection terminals can be readily performed. As a result, even when the arrangement pitch of the lead electrodes changes when the circuit substrate expands or contracts due to heat and/or humidity, the narrow pitch of the lead electrodes can be accommodated and the lead electrodes and the connection terminals can be connected with good precision, and the reliability of the electronic device can be improved while the electronic device can be made smaller and lighter.

Also, an electronic equipment in accordance with an embodiment of the present invention is characterized in comprising: a circuit substrate having radially extending lead electrodes formed thereon; a semiconductor chip mounted on the circuit substrate; protruded electrodes disposed on the semiconductor chip and shifted in a direction away from adjacent ones of the lead electrodes; and an electronic device connected to the semiconductor chip through the lead electrodes.

Accordingly, even in the case where lead electrodes are radially extended, clearances between the protruded electrodes and adjacent ones of the lead electrodes can be increased. For this reason, positioning of the lead electrodes with respect to the protruded electrodes can be readily performed, while accommodating changes in the arrangement pitch of the lead electrodes, and the reliability of the electronic equipment can be improved while the electronic equipment can be made smaller and lighter.

Also, a method for manufacturing a semiconductor module in accordance with an embodiment of the present invention is characterized in comprising: a step of positioning a semiconductor chip such that protruded electrodes mounted on the semiconductor chip are disposed on radially extending lead electrodes; and a step of mounting the semiconductor chip on a circuit substrate having the lead electrodes formed thereon by bonding the protruded electrodes to the lead electrodes.

Accordingly, even when the arrangement pitch of the lead electrodes changes when the circuit substrate expands or contracts due to heat and/or humidity, the lead electrodes and the protruded electrodes can be connected with good precision, while preventing the protruded electrodes from contacting adjacent ones of the lead electrodes, and the reliability of the semiconductor module can be improved while the semiconductor module can be made smaller and lighter.

### BRIEF DESCRIPTION OF THE DRAWINGS

FIG. 1 is a plan view of the structure of radially extending lead electrodes.

FIG. 2 is a plan view indicating a method for disposing a semiconductor chip.

FIG. 3 is a plan view indicating the structure of protruded electrodes in accordance with a second embodiment of the present invention.

FIG. 4 is a plan view indicating the structure of protruded electrodes in accordance with a third embodiment of the present invention.

FIG. 5 is a plan view indicating the structure of protruded electrodes in accordance with a fourth embodiment of the present invention.

FIG. 6 is a plan view indicating the structure of protruded electrodes in accordance with a fifth embodiment of the present invention.

### DETAILED DESCRIPTION

A semiconductor device and a method for manufacturing the same in accordance with embodiments of the present invention will be described below with reference to the accompanying drawings.

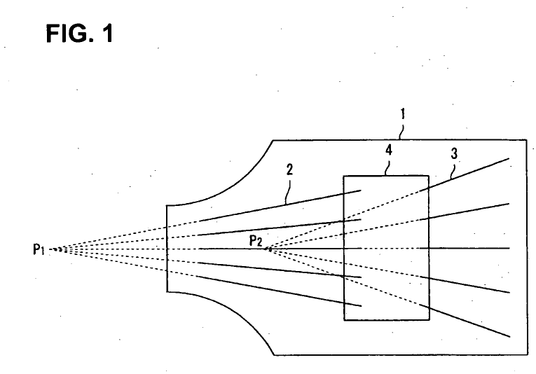

FIG. 1 shows a plan view illustrating the structure of radially extending lead electrodes in accordance with a first embodiment of the present invention.

In FIG. 1, a film substrate 1 is provided thereon with a semiconductor chip mounting region 4, and lead electrodes 2 and 3 formed in a manner to extend respectively across the semiconductor chip mounting region 4. Here, the lead electrodes 2 that extend across one end of the semiconductor chip mounting region 4 are radially extended on the film substrate 1 with a (virtual) point P1 as their center, and the lead electrodes 3 that extend across the other end of the semiconductor chip mounting region 4 are radially extended on the film substrate 1 with a (virtual) point P2 as their center.

Here, by forming the lead electrodes 2 and 3 on the film substrate 1 in a manner to extend radially, the accuracy in alignment with the lead electrodes 2 and 3 can be improved, even when the arrangement pitch of the lead electrodes 2 and 3 changes due to expansion or contraction of the film substrate 1 which may be caused by heat and/or humidity.

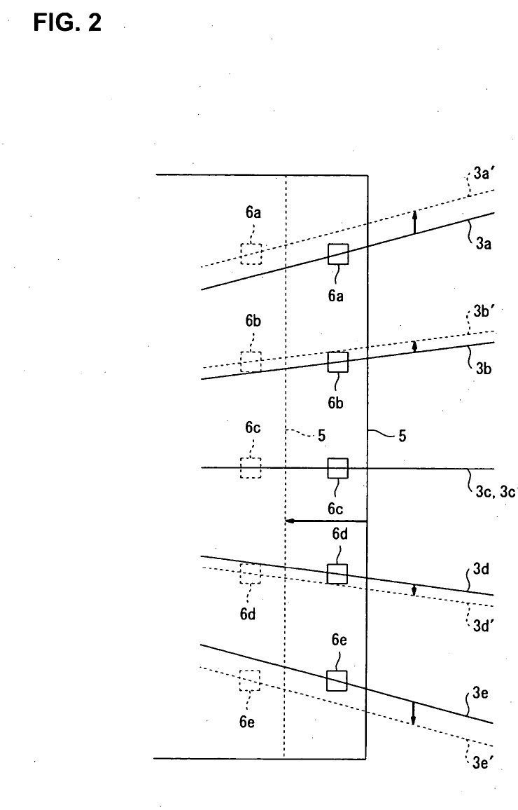

FIG. 2 is a plan view indicating a method for placing the semiconductor chip 5 on the film substrate 1 having the lead electrodes 2 and 3 shown in FIG. 1 formed thereon.

In FIG. 2, the film substrate 1 of FIG. 1 includes lead electrodes 3a-3e formed thereon, wherein the lead electrodes 3a-3e are assumed to extend radially on the film substrate 1 with the point P2 of FIG. 1 as their center. Also, the semiconductor chip 5 is provided thereon with protruded electrodes 6a-6e, which are assumed to be placed corresponding to arrangement pitches of the lead electrodes 3a-3e of the film substrate 1. When no expansion or contraction occurs in the film substrate 1, the arrangement pitches of the lead electrodes 3a-3e do not change. For this reason, by positioning the semiconductor chip 5 such that the protruded electrodes 6a-6e are respectively disposed on the lead electrodes 3a-3e, the semiconductor chip 5 can be mounted on the film substrate 1.

On the other hand, if the film substrate 1 expands due to heat and/or humidity or the like, the arrangement pitches of the lead electrodes 3a-3e change, and the positions of the lead electrodes 3a-3e shift to positions of the lead electrodes indicated as 3a′-3e′. Here, since the lead electrodes 3a-3e are radially extended, the lead electrodes 3a′-3e′ maintains the state in which they extend radially on the film substrate 1 with the point P2 of FIG. 1 as their center, even when the film substrate 1 expands.

When the positions of the lead electrodes 3a-3e shift to the positions of the lead electrodes indicated as 3a′-3e′, the position of the semiconductor chip 5 is shifted along the extending direction of the lead electrodes 3a′-3e′. Since the lead electrodes 3a′-3e′ are radially extended, by shifting the position of the semiconductor chip 5 along the extending direction of the lead electrodes 3a′-3e′, the semiconductor chip 5 can be positioned such that the protruded electrodes 6a-6e are respectively disposed on the lead electrodes 3a′-3e′, and the semiconductor chip 5 can be mounted on the film substrate 1.

It is noted here that, as the lead electrodes 3a-3e are radially extended on the film substrate 1, the lead electrodes 3b and 3d that are adjacent to the protruded electrode 6c are disposed in a manner to approximate to the protruded electrode 6c; the lead electrode 3a that is adjacent to the protruded electrode 6b is disposed in a manner to approximate to the protruded electrode 6b; and the lead electrode 3e that is adjacent to the protruded electrode 6d is disposed in a manner to approximate to the protruded electrode 6d. For this reason, for example, the protruded electrode 6b may be disposed away from the lead electrode 3a, and the protruded electrode 6d may be disposed away from the lead electrode 3e. More specifically, the protruded electrodes 6b and 6d can be disposed to be shifted in a direction toward the protruded electrode 6c.

Accordingly, even in the case where the lead electrodes 3a-3e extend in a diagonal direction, the position of the protruded electrodes 6a-6e can be adjusted such that the protruded electrodes 6a-6e do not contact the adjacent ones of the lead electrodes 3a-3e. For this reason, even in the case where the lead electrodes 3a-3e are radially extended, clearances between the protruded electrodes 6a-6e and the adjacent ones of the lead electrodes 3a-3e can be increased, and positioning of the lead electrodes 3a-3e with respect to the protruded electrodes 6a-6e can be readily performed.

As a result, even when the arrangement pitch of the lead electrodes 3a-3e changes when the film substrate 1 expands or contracts due to heat and/or humidity, the narrow pitch of the lead electrodes 3a-3e can be accommodated, the lead electrodes 3a-3e and the protruded electrodes 6a-6e can be connected with good precision, and the reliability of the semiconductor module can be improved while the semiconductor module can be made smaller and lighter.

Also, as the lead electrodes 3a-3e are radially extended on the film substrate 1, inclination amounts of the lead electrodes 3a-3e that are adjacent respectively to the protruded electrodes 6a-6e are different from one another. For this reason, shift amounts of the respective protruded electrodes 6a-6e may be adjusted based on inclinations of the lead electrodes 3a-3e in a manner that separations between the protruded electrodes 6a-6e and adjacent ones of the lead electrodes 3a-3e increase.

It is noted that, in the embodiment in FIG. 1, the method in which the lead electrodes 2 and 3 are formed on the film substrate 1 is described. However, instead of the film substrate 1, another substrate, such as, for example, a printed circuit board, a multiple-layered wiring substrate, a build-up substrate, a tape substrate or a glass substrate may be used. Also, the material of the substrate on which the lead electrodes 2 and 3 are formed may be, for example, polyimide resin, glass-epoxy resin, BT resin, a composite of aramid and epoxy, ceramics or the like. Also, as the protruded electrodes 6a-6e,for example, Au bumps, Au/Ni bumps, Cu bumps or Ni bumps coated with solder material, solder balls or the like can be used. Also, as the lead electrodes 2 and 3, for example, copper (Cu), iron (Fe), gold (Au), silver (Ag), copper (Cu) coated with solder material, copper (Cu) coated with gold (Au) or the like can be used.

Also, for connecting the protruded electrodes 6a-6e to the lead electrodes 3a-3e, for example, metal bonding such as solder bonding or alloy bonding may be used, or another pressure bonding such as ACF (Anisotropic Conductive Film) bonding, NCF (Nonconductive Film) bonding, ACP (Anisotropic Conductive Paste) bonding, NCP (Nonconductive Paste) bonding or the like may be used. Also, in the embodiment described above, the method is described with the protruded electrodes 6a-6e that are linearly arranged. However, the protruded electrodes 6a-6e can be arranged in a staggered configuration.

Also, in the embodiment described above, the description is made, using a COF (chip on film) as an example. However, the present invention may be applied to TCP (tape carrier package), COG (chip on glass) and TCM (tape carrier module).

FIG. 3 is a plan view indicating the structure of protruded electrodes in accordance with a second embodiment of the present invention.

In FIG. 3, protruded electrodes 12 are linearly arranged on a semiconductor chip 11, and radially extending lead electrodes 13 are formed on a film substrate. By bonding the protruded electrodes 12 to the lead electrodes 13, the semiconductor chip 11 can be mounted on the film substrate.

It is noted here that a bonding surface of each protruded electrode 12 can be in a square shape. Compared to the case of rectangular protruded electrodes 12′ in which the distance between the protruded electrode 12′ and an adjacent one of the lead electrodes 13 is D1, the distance between the protruded electrode 12 and an adjacent one of the lead electrodes 13 is D2 in the case where the protruded electrode 12 is in a square shape, whereby the protruded electrode 12 can be removed away from the adjacent lead electrode 13 that extends diagonally.

For this reason, even in the case where the lead electrodes 13 are radially extended, clearances between the protruded electrodes 12 and adjacent ones of the lead electrodes 13 can be increased, and positioning of the lead electrodes 13 with respect to the protruded electrodes 12 can be readily performed. As a result, even when the arrangement pitch of the lead electrodes 13 changes when the film substrate expands or contracts due to heat and/or humidity, the narrow pitch of the lead electrodes 13 can be accommodated and the lead electrodes 13 and the protruded electrodes 12 can be connected with good precision, and the reliability of the semiconductor module can be improved while the semiconductor module can be made smaller and lighter.

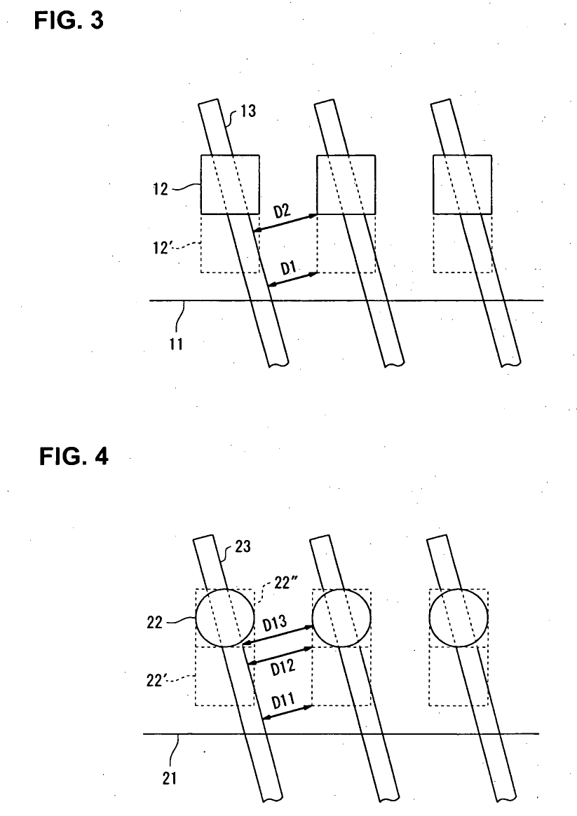

FIG. 4 is a plan view indicating the structure of protruded electrodes in accordance with a third embodiment of the present invention.

In FIG. 4, protruded electrodes 22 are linearly arranged on a semiconductor chip 21, and radially extending lead electrodes 23 are formed on a film substrate. By bonding the protruded electrodes 22 to the lead electrodes 23, the semiconductor chip 21 can be mounted on the film substrate. It is noted here that a bonding surface of each protruded electrode 22 can be in a circular shape.

Compared to the case of rectangular protruded electrodes 22′ in which the distance between the protruded electrode 22′ and an adjacent one of the lead electrodes 23 is D11, and to the case of square protruded electrodes 22″ in which the distance between the protruded electrode 22″ and an adjacent one of the lead electrodes 23 is D12, the distance between the protruded electrode 22 and an adjacent one of the lead electrodes 23 is D13 in the case where the protruded electrode 22 is in a circular shape, whereby the protruded electrode 22 can be removed farther away from the adjacent lead electrode 23 that extends diagonally.

For this reason, even in the case where the lead electrodes 23 are radially extended, clearances between the protruded electrodes 22 and adjacent ones of the lead electrodes 23 can be further increased, and positioning of the lead electrodes 23 with respect to the protruded electrodes 22 can be more readily performed. As a result, even when the arrangement pitch of the lead electrodes 23 changes when the film substrate expands or contracts due to heat and/or humidity, the narrow pitch of the lead electrodes 23 can be accommodated and the lead electrodes 23 and the protruded electrodes 22 can be connected with good precision, and the reliability of the semiconductor module can be further improved while the semiconductor module can be made smaller and lighter.

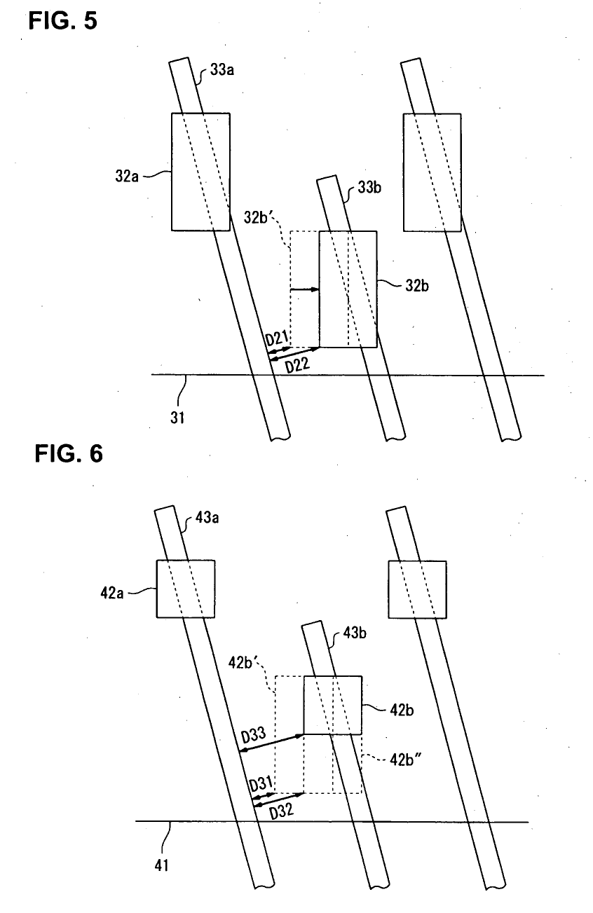

FIG. 5 is a plan view indicating the structure of protruded electrodes in accordance with a fourth embodiment of the present invention.

In FIG. 5, protruded electrodes 32a and 32b are arranged on a semiconductor chip 31 in a staggered fashion, and radially extending lead electrodes 33a and 33b are formed on a film substrate. By bonding the protruded electrodes 32a and 32b onto the lead electrodes 33a and 33b, the semiconductor chip 31 can be mounted on the film substrate.

It is noted here that, when the lead electrodes 33a and 33b are radially extended, and if outer side protruded electrode 32b′ are to be arranged at equal intervals between the inner side protruded electrodes 32a, the lead electrode 33a that is connected to the inner side protruded electrode 32a is placed in the vicinity of the outer side protruded electrode 32b′, wherein the distance between the lead electrode 33a that is connected to the inner side protruded electrode 32a and the outer side protruded electrode 32b′ would be D21.

Accordingly, the outer side protruded electrodes 32b′ may be arranged offset with respect to the arrangement of the inner side protruded electrodes 32a, thereby shifting the positions of the outer side protruded electrodes 32b′ to positions of the protruded electrodes indicated as 32b. Consequently, the outer side protruded electrode 32b can be placed away from the lead electrode 33a that is connected to the inner side protruded electrode 32a, and the distance between the lead electrode 33a that is connected to the inner side protruded electrode 32a and the outer side protruded electrode 32b would become to be D22.

For this reason, even in the case where the lead electrodes 33a and 33b are radially extended, clearances between the protruded electrodes 32a and 32b and adjacent ones of the lead electrodes 33a and 33b can be increased, and positioning of the lead electrodes 33a and 33b with respect to the protruded electrodes 32a and 32b can be readily performed. As a result, even when the arrangement pitches of the lead electrodes 33a and 33b change when the film substrate expands or contracts due to heat and/or humidity, the narrow pitch of the lead electrodes 33a and 33b can be accommodated and the lead electrodes 33a and 33b and the protruded electrodes 32a and 32b can be connected with good precision, and the reliability of the semiconductor module can be improved while the semiconductor module can be made smaller and lighter

It is noted that, as the lead electrodes 33a and 33b are radially extended on the film substrate, inclination amounts of the lead electrodes 33a and 33b that are respectively adjacent to the protruded electrodes 32a and 32b are different from one another. For this reason, shift amounts of the respective protruded electrodes 32a and 32b may be adjusted based on inclinations of the lead electrodes 33a and 33b.

FIG. 6 is a plan view indicating the structure of protruded electrodes in accordance with a fifth embodiment of the present invention.

In FIG. 6, protruded electrodes 42a and 42b each having a square bonding surface are arranged on a semiconductor chip 41 in a staggered fashion, and radially extending lead electrodes 43a and 43b are formed on a film substrate. By bonding the protruded electrodes 42a and 42b onto the lead electrodes 43a and 43b, the semiconductor chip 41 can be mounted on the film substrate.

It is noted here that, when the lead electrodes 43a and 43b are radially extended, and if outer side protruded electrode 42b′ are to be arranged at equal intervals between the inner side protruded electrodes 42a, the lead electrode 43a that is connected to the inner side protruded electrode 42a is placed in the vicinity of the outer side protruded electrode 42b′, wherein the distance between the lead electrode 43a that is connected to the inner side protruded electrode 42a and the outer side protruded electrode 42b′ would be D31.

Accordingly, the outer side protruded electrodes 42b′ may be arranged offset with respect to the arrangement of the inner side protruded electrodes 42a, thereby shifting the positions of the outer side protruded electrodes 42b′ to positions of the protruded electrodes indicated as 42b″. Consequently, the outer side protruded electrode 42″b can be placed away from the lead electrode 43a that is connected to the inner side protruded electrode 42a, and the distance between the lead electrode 43a that is connected to the inner side protruded electrode 42a and the outer side protruded electrode 42b″ would become to be D32.

Compared to the case of rectangular protruded electrodes 42b″ in which the distance between the protruded electrode 42b″ and an adjacent one of the lead electrodes 43a is D32, the distance between the protruded electrode 42b and an adjacent one of the lead electrodes 43a is D13 in the case where the protruded electrode 42b is in a circular shape, whereby the protruded electrode 42b can be removed farther away from the adjacent lead electrode 43a that extends diagonally.

For this reason, even in the case where the lead electrodes 43a and 43b are radially extended, clearances between the protruded electrodes 42a and 42b and adjacent ones of the lead electrodes 43a and 43b can be further increased, and positioning of the lead electrodes 43a and 43b with respect to the protruded electrodes 42a and 42b can be readily performed. As a result, even when the arrangement pitches of the lead electrodes 43a and 43b change when the film substrate expands or contracts due to heat and/or humidity, the narrow pitch of the lead electrodes 43a and 43b can be accommodated and the lead electrodes 43a and 43b and the protruded electrodes 42a and 42b can be connected with good precision, and the reliability of the semiconductor module can be improved while the semiconductor module can be made smaller and lighter

It is noted that, as the lead electrodes 43a and 43b are radially extended on the film substrate, inclination amounts of the lead electrodes 43a and 43b that are adjacent respectively to the protruded electrodes 42a and 42b are different from one another. For this reason, shift amounts of the respective protruded electrodes 42a and 42b may be adjusted based on inclinations of the lead electrodes 43a and 43b.

Also, in the embodiment in FIG. 6, the method is described with the protruded electrodes 42a and 42b each having a square bonding surface. However, the bonding surface of each of the protruded electrodes 42a and 42b can be in a circular shape. Consequently, clearances between the protruded electrodes 42a and 42b and adjacent ones of the lead electrodes 43a and 43b can be further increased, and positioning of the lead electrodes 43a and 43b with respect to the protruded electrodes 42a and 42b can be more readily performed.

It is noted here that the semiconductor device described above is applicable to electronic equipment, such as, for example, liquid crystal display devices, portable telephones, portable information terminals, video cameras, digital cameras, MD (Mini Disc) players, the electronic equipment can be further reduced in size and weight, and the reliability of the electronic equipment can be improved.

Also, in the embodiments described above, although the description is made using the method for mounting a semiconductor chip on a circuit substrate as an example, the present invention is not necessarily limited to the method for mounting a semiconductor chip. For example, a ceramic element such as a surface acoustic wave (SAW) element, an optical element such as an optical modulator, an optical switch or the like, or any of a variety of sensors such as a magnetic sensor, a bio-sensor and the like may be mounted.

1. A semiconductor device comprising:
a semiconductor chip; and
protruded electrodes arranged on the semiconductor chip in a straight line, the protruded electrodes having bonding surfaces that are each in at least one of a square shape and a circular shape.

2. A semiconductor device comprising:
a semiconductor chip; and
protruded electrodes arranged on the semiconductor chip in a staggered configuration, wherein one row of the protruded electrodes in the staggered arrangement is offset with respect to another row of the protruded electrodes in the staggered arrangement.

3. A semiconductor device according to claim 2, wherein bonding surfaces of the protruded electrodes are each in at least one of a square shape and a circular shape.

4. A semiconductor module comprising:
a circuit substrate having radially extending lead electrodes thereon;
a semiconductor chip mounted on the circuit substrate; and
protruded electrodes disposed on the semiconductor chip, the protruded electrodes being shifted in a direction away from adjacent ones of the lead electrodes.

5. A semiconductor module comprising:
a substrate having divergent lead electrodes thereon;
a chip mounted on the circuit substrate; and
protruded electrodes disposed on the chip,
wherein an amount of deviation of the protruded electrodes relative to the lead electrodes is determined based on inclinations of the lead electrodes.

6. A semiconductor device comprising:
a circuit substrate having radially extending lead electrodes thereon;
an electronic device mounted on the circuit substrate; and
connection terminals disposed on the electronic device, the connection terminals being shifted in a direction away from adjacent ones of the lead electrodes.

7. An electronic equipment comprising:
a circuit substrate having radially extending lead electrodes thereon;
a semiconductor chip mounted on the circuit substrate;
protruded electrodes disposed on the semiconductor chip, the protruded electrodes being shifted in a direction away from adjacent ones of the lead electrodes; and
an electronic device connected to the semiconductor chip through the lead electrodes.

8. A method for manufacturing a semiconductor module, comprising:
a step of positioning a semiconductor chip such that protruded electrodes mounted on the semiconductor chip are disposed on radially extending lead electrodes; and
a step of mounting the semiconductor chip on a circuit substrate having the lead electrodes formed thereon by bonding the protruded electrodes to the lead electrodes.
